(19) United States
(12) Patent Application Publication
(10) Pub. No.: US 2025/0105167 A1
(43) Pub. Date: Mar. 27, 2025

(54) METHOD OF PROCESSING WAFER

(71) Applicant: DISCO CORPORATION, Tokyo (JP)

(72) Inventors: Naoko YAMAMOTO, Tokyo (JP); Atsushi KUBO, Tokyo (JP)

(21) Appl. No.: 18/887,709

(22) Filed: Sep. 17, 2024

(30) Foreign Application Priority Data
Sep. 21, 2023 (JP) 2023-156475

(51) Int. Cl. H01L 23/544; H01L 21/04; H01L 21/78

(52) U.S. Cl. CPC H01L 23/544; H01L 21/0445; H01L 21/78; H01L 2223/54493

(57) ABSTRACT

A method is of processing a wafer that includes on a side of a front surface a plurality of intersecting planned dividing lines and a plurality of devices formed in respective areas defined by the planned dividing lines, and a metal layer laminated on a side of a back surface. The method includes: forming a mark indicating positions of the planned dividing lines of the wafer on the back surface; and dicing the wafer from the side of the back surface using the formed mark as a reference to divide the wafer into individual chips.

### CROSS-REFERENCE TO RELATED APPLICATION(S)

The present application claims priority to and incorporates by reference the entire contents of Japanese Patent Application No. 2023-156475 filed in Japan on Sep. 21, 2023.

### BACKGROUND

The present disclosure relates to a method of processing a wafer having a front surface on which a plurality of devices are formed and a back surface on which a metal layer is laminated.

In order to prevent foreign matter from adhering to a device during cutting, dicing by bonding a front surface side of a wafer to a tape has been widely used (see, for example, JP H6-232255 A).

In a dicing method described in JP H6-232255 A, when dicing is performed from a back surface side of a wafer, a pattern on a front surface side is detected using an infrared camera, a position of a planned dividing line is identified based on the pattern, and dicing is performed by a cutting blade along the planned dividing line.

However, in the case of a wafer including a metal layer laminated on a back surface side, it is difficult to identify a position of a planned dividing line using the infrared camera, and improvement is earnestly desired.

### SUMMARY

A method according to one aspect of the present disclosure is of processing a wafer, the wafer including on a side of a front surface a plurality of intersecting planned dividing lines and a plurality of devices formed in respective areas defined by the planned dividing lines, and a metal layer laminated on a side of a back surface. The method includes: forming a mark indicating positions of the planned dividing lines of the wafer on the back surface; and dicing the wafer from the side of the back surface using the formed mark as a reference to divide the wafer into individual chips.

### BRIEF DESCRIPTION OF THE DRAWINGS

FIG. 1 is a perspective view schematically illustrating a wafer to be processed by a method of processing a wafer according to a first embodiment;

FIG. 2 is a flowchart illustrating a flow of the method of processing a wafer according to the first embodiment;

FIG. 3 is a perspective view illustrating the wafer after a tape arrangement step of the method of processing a wafer illustrated in FIG. 2;

FIG. 4 is a perspective view illustrating a configuration example of a processing apparatus that performs a mark formation step of the method of processing a wafer illustrated in FIG. 2;

FIG. 5 is a plan view of the wafer after the mark formation step of the method of processing a wafer illustrated in FIG. 2 as viewed from a back surface side;

FIG. 6 is a plan view of another example of the wafer illustrated in FIG. 5 as viewed from the back surface side; and

FIG. 7 is a perspective view schematically illustrating a dicing step of the method of processing a wafer illustrated in FIG. 2.

### DETAILED DESCRIPTION

Embodiments of the present disclosure will be described in detail with reference to the drawings. The present invention is not limited by the contents described in the following embodiment. In addition, components to be described below include those that can be easily assumed by those skilled in the art and those that are substantially the same. Furthermore, configurations described below can be appropriately combined. In addition, various omissions, substitutions, or changes of the configurations can be made within a scope not departing from the gist of the present invention.

### First Embodiment

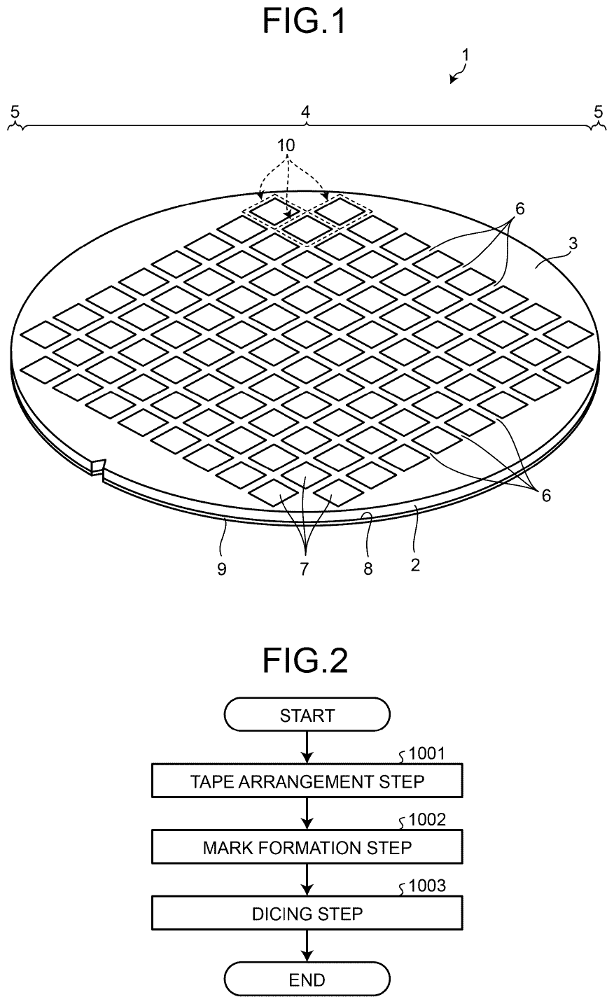

A method of processing a wafer according to a first embodiment of the present disclosure will be described with reference to the drawings. FIG. 1 is a perspective view schematically illustrating a wafer to be processed by a method of processing a wafer according to the first embodiment. FIG. 2 is a flowchart illustrating a flow of the method of processing a wafer according to the first embodiment.

### Wafer

The method of processing a wafer according to the first embodiment is a method of dicing (which corresponds to processing) a wafer 1. The wafer 1 illustrated in FIG. 1 to be processed by the method of processing a wafer according to the first embodiment is a disk-shaped semiconductor device wafer, optical device wafer, or the like using silicon, sapphire, gallium arsenide, silicon carbide (Sic), or the like as a substrate 2. In the first embodiment, the substrate 2 of the wafer 1 is made of SiC.

As illustrated in FIG. 1, the wafer 1 includes a device area 4 on a front surface 3 of the substrate 2 and an outer peripheral marginal area 5 surrounding the device area 4. The device area 4 includes, on the front surface 3 side, a plurality of intersecting planned dividing lines 6 and devices 7 formed in respective areas defined by the planned dividing lines 6.

Examples of the devices 7 include an integration circuit such as an integrated circuit (IC) or a large scale integration (LSI), an image sensor such as a charge coupled device (CCD) or a complementary metal oxide semiconductor (CMOS), an optical element such as a light-emitting diode (LED), and a memory (semiconductor storage device). The outer peripheral marginal area 5 surrounds the entire periphery of the device area 4, and is an area where the devices 7 are not formed on the front surface 3 of the substrate 2.

In addition, in the first embodiment, the wafer 1 includes a metal layer 9 laminated on a back surface 8 on the back side of the front surface 3 of the substrate 2. Since the wafer 1 includes the metal layer 9 formed on the back surface 8, the planned dividing lines 6 cannot be detected even if an image is captured by an infrared camera from the back surface 8 side.

### Method of Processing Wafer

Next, the method of processing a wafer according to the first embodiment will be described. The method of processing a wafer according to the first embodiment is a method of dicing the wafer 1 to divide the wafer 1 into individual chips 10. Note that the chips 10 include a part of the substrate 2 and the chips 10 formed on the front surface 3 of the substrate 2. As illustrated in FIG. 2, the method of processing a wafer according to the first embodiment includes a tape arrangement step 1001, a mark formation step 1002, and a dicing step 1003.

### Tape Arrangement Step

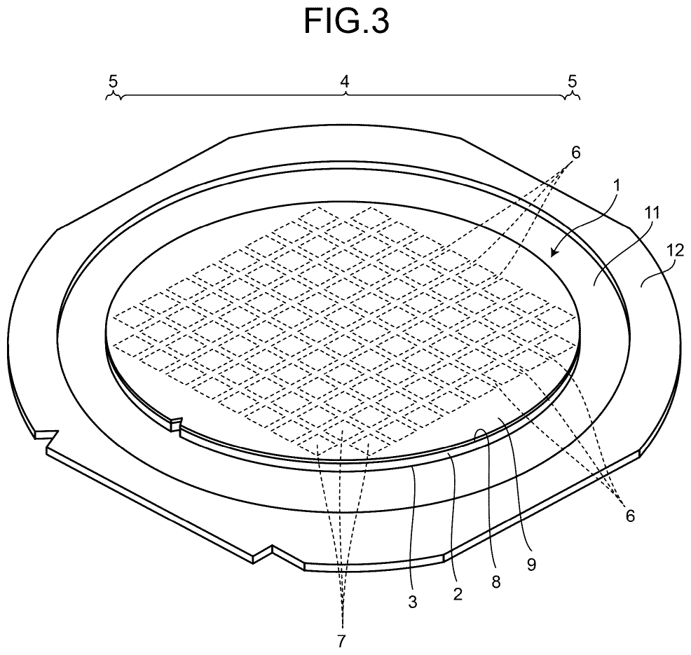

FIG. 3 is a perspective view illustrating the wafer after the tape arrangement step of the method of processing a wafer illustrated in FIG. 2. The tape arrangement step 1001 is a step of arrangement a tape 11 on the front surface 3 of the wafer 1. In the tape arrangement step 1001 of the first embodiment, as illustrated in FIG. 3, a central portion of the tape 11 having a disk shape whose diameter is larger than t the wafer 1 is bonded to the front surface 3 of the wafer 1, and a frame 12 having a ring shape whose inner diameter is larger than an outer diameter of the wafer 1 is bonded to an outer edge portion of the tape 11.

Note that the tape 11 in the first embodiment is an adhesive tape including a base material layer made of a resin having non-adhesiveness and flexibility, and a glue layer laminated on the base material layer and made of a resin having adhesiveness and flexibility, the glue layer being bonded to the wafer 1 and the frame 12. However, in the present disclosure, the tape 11 may be a sheet that does not include a glue layer but includes only a base material layer which is made of a thermoplastic resin, exhibits an adhesive force by heating, and is thermocompression-bonded to the wafer 1 and the frame 12.

In the first embodiment, in the tape arrangement step 1001, the front surface 3 of the wafer 1 is bonded to the tape 11 equipped with the frame 12 in the outer edge portion, so that the wafer 1 is supported by the frame 12 to expose the metal layer 9 on the back surface 8 side of the wafer 1.

### Processing Apparatus

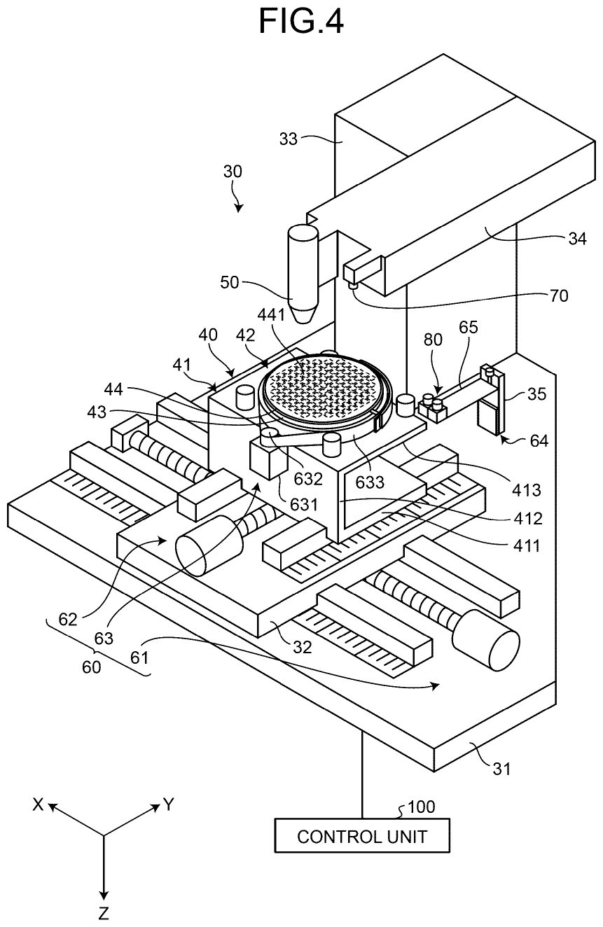

The mark formation step 1002 of the method of processing a wafer illustrated in FIG. 2 is performed by a processing apparatus 30 illustrated in FIG. 4. Next, the processing apparatus 30 will be described. FIG. 4 is a perspective view illustrating a configuration example of the processing apparatus that performs the mark formation step of the method of processing a wafer illustrated in FIG. 2.

The processing apparatus 30 illustrated in FIG. 4 is a laser processing apparatus that holds the wafer 1 on a holding table 42 of a holding unit 40 and forms marks 13 indicating positions of the planned dividing lines 6 of the wafer 1 on the metal layer 9 laminated on the back surface 8 side. As illustrated in FIG. 4, the processing apparatus 30 includes the holding unit 40, a laser beam irradiation unit 50, a moving unit 60, an upper imaging unit 70, a lower imaging unit 80, and a control unit 100.

As illustrated in FIG. 4, the holding unit 40 includes: a table base 41 moved by the moving unit 60 in an X-axis direction parallel to the horizontal direction and a Y-axis direction parallel to the horizontal direction and orthogonal to the X-axis direction; and the holding table 42 provided on the table base 41 so as to be rotatable about an axis parallel to a Z-axis direction along the vertical direction.

In the first embodiment, the table base 41 includes: a lower plate 411 moved in the X-axis direction and the Y-axis direction by the moving unit 60 and is parallel to the horizontal direction; a side plate 412 that is erected from an outer edge of the lower plate 411; and an upper plate 413 that has an outer edge continuous with an upper end of the side plate 412, is parallel to the lower plate 411, and has, at the center, a circular hole having the same diameter as a holding portion 44 to be described later.

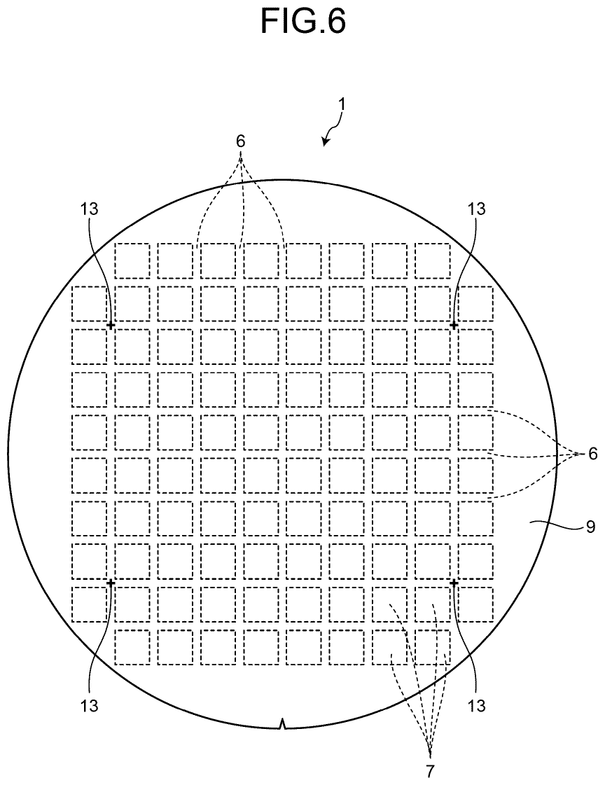

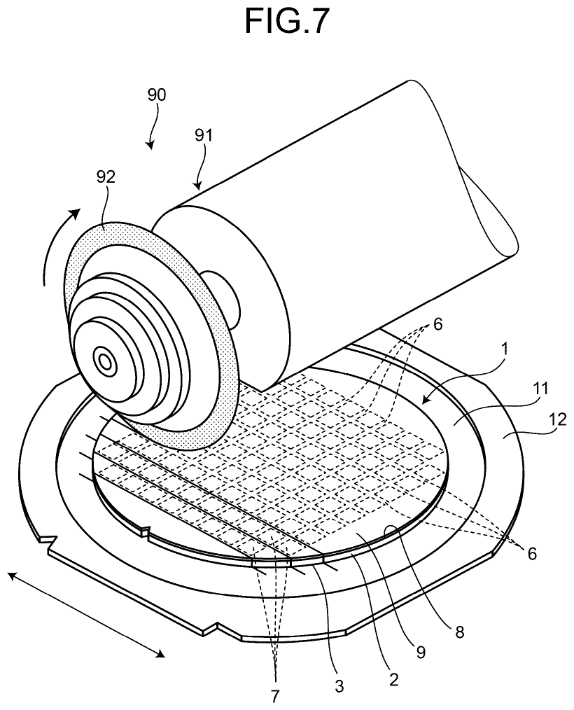

The holding table 42 holds the wafer 1 on a holding surface 441 and is supported by the upper plate 413 so as to be rotatable about the axis. As illustrated in FIG. 6, the holding table 42 includes: an annular base 43 that has a ring shape, is supported by the upper plate 413 so as to be rotatable about the axis parallel to the Z-axis direction, and has an opening at the center; and the holding portion 44 that has a disk shape, is attached inside the opening of the annular base 43 and is made of a transparent material.

The holding portion 44 is made of the transparent material that is transparent, such as quartz glass, borosilicate glass, sapphire, calcium fluoride, lithium fluoride, or magnesium fluoride, and has an upper surface serving as the holding surface 441 that holds the wafer 1. That is, the holding table 42 includes the holding surface 441. In the first embodiment, the front surface 3 side of the wafer 1 is placed on the holding surface 441 of the holding portion 44 with the tape 11 interposed therebetween. A suction groove connected to a vacuum suction source is formed in the holding surface 441 of the holding portion 44.

When the holding surface 441 is sucked by the vacuum suction source, the holding table 42 sucks and holds the wafer 1 placed on the holding surface 441 onto the holding surface 441 with the tape 11 interposed therebetween. Since the holding portion 44 is made of the transparent material in the first embodiment, at least a part of the holding surface 441 of the holding table 42 is made of the transparent material.

The moving unit 60 includes: an X-axis moving unit 61 which is a processing feed unit; a Y-axis moving unit 62 which is an indexing feed unit; and a rotary moving unit 63 which rotates the holding table 42 about the axis parallel to the Z-axis direction.

The X-axis moving unit 61 is installed on an apparatus body 31. The X-axis moving unit 61 moves a moving table 32 on which the Y-axis moving unit 62 is installed in the X-axis direction, thereby relatively moving the holding table 42 and the laser beam irradiation unit 50 in the X-axis direction. The X-axis moving unit 61 moves the holding table 42 in the X-axis direction over a loading and unloading area where the wafer 1 is loaded onto and unloaded from the holding table 42 and a processing area where the wafer 1 held by the wafer 1 is subjected to laser processing.

The Y-axis moving unit 62 is installed on the moving table 32 moved in the X-axis direction by the X-axis moving unit 61. The Y-axis moving unit 62 moves the lower plate 411 of the table base 41 of the holding unit 40 in the Y-axis direction, thereby relatively moving the holding table 42 and the laser beam irradiation unit 50 in the Y-axis direction.

The X-axis moving unit 61 and the Y-axis moving unit 62 each include a known ball screw provided so as to be rotatable about an axis, a known motor that rotates the ball screw about the axis, and a known guide rail that supports the moving table 32 or the table base 41 so as to be movable in the X-axis direction or the Y-axis direction.

The rotary moving unit 63 rotates the holding table 42 about the axis parallel to the Z-axis direction. The rotary moving unit 63 rotates the holding table 42 about the axis within a range of more than 180 degrees and less than 360 degrees. The rotary moving unit 63 includes a motor 631 fixed to the side plate 412 of the table base 41, a pulley 632 connected to an output shaft of the motor 631, and a belt 633 that is wound around and attached to the outer periphery of the annular base 43 of the holding table 42 and is rotated about the axis by the pulley 632.

When the motor 631 is rotated, the rotary moving unit 63 rotates the holding table 42 about the axis via the pulley 632 and the belt 633. In addition, in the first embodiment, the rotary moving unit 63 can rotate the holding table 42 by 220 degrees in both one direction about the axis and the other direction opposite to the one direction.

The laser beam irradiation unit 50 is a processing unit that condenses and emits a pulsed laser beam to the wafer 1 held on the holding surface 441 of the holding table 42 to perform the laser processing on the metal layer 9 of the wafer 1. In the first embodiment, as illustrated in FIG. 4, a part of the laser beam irradiation unit 50 is disposed at a distal end of a support column 34 whose proximal end portion is supported by an upright column 33 erected from the apparatus body 31.

The laser beam irradiation unit 50 includes an oscillator that emits a laser beam with a wavelength having absorbability with respect to the metal layer 9, and a condenser lens that condenses the laser beam emitted from the oscillator and irradiates the wafer 1 with the laser beam.

The upper imaging unit 70 is fixed to the distal end of the support column 34. In the first embodiment, the upper imaging unit 70 is disposed at a position aligned with the condenser lens of the laser beam irradiation unit 50 in the X-axis direction. The upper imaging unit 70 includes a plurality of imaging elements that capture images of the wafer 1 held on the holding table 42 from above. The imaging element is, for example, a charge-coupled device (CCD) imaging element or a complementary MOS (CMOS) imaging element. The upper imaging unit 70 captures an image of the wafer 1 held by the holding portion 44 of the holding table 42 and outputs the obtained image to the control unit 100.

The lower imaging unit 80 captures an image of the front surface 3 of the wafer 1 held on the holding table 42 through the holding portion 44 of the holding table 42. The lower imaging unit 80 captures an image of the front surface 3 side of the wafer 1 held by the holding portion 44 of the holding table 42 from below the wafer 1 through the holding portion 44.

The lower imaging unit 80 is disposed adjacent to the moving table 32 in the Y-axis direction and adjacent to the upright column 33 in the X-axis direction. The lower imaging unit 80 is disposed to be movable in the Z-axis direction by a Z-axis moving unit 64 provided on an upright column 35 erected from the apparatus body 31. In the first embodiment, the lower imaging unit 80 is attached to a distal end of a horizontal extension member 65 whose proximal end portion is movable in the Z-axis direction by the Z-axis moving unit 64.

The Z-axis moving unit 64 includes a known ball screw provided so as to be rotatable about an axis, a known motor that rotates the ball screw about the axis, and a known guide rail that supports the lower imaging unit 80 so as to be movable in the Z-axis direction.

The lower imaging unit 80 enters between the lower plate 411 and the upper plate 413 of the table base 41 moved by the Y-axis moving unit 62 and is arranged below the holding portion 44 of the holding table 42. The lower imaging unit 80 includes an imaging element that captures an image of the wafer 1 held on the holding table 42 from below through the holding portion 44. The imaging element is, for example, a charge-coupled device (CCD) imaging element or a complementary MOS (CMOS) imaging element. The lower imaging unit 80 captures an image of the wafer 1 held on the holding table 42 and outputs the obtained image to the control unit 100.

In addition, the processing apparatus 30 includes an X-axis direction position detection unit (not illustrated) configured to detect a position of the holding table 42 in the X-axis direction and a Y-axis direction position detection unit (not illustrated) configured to detect a position of the holding table 42 in the Y-axis direction. Each of the X-axis direction position detection unit and the Y-axis direction position detection unit can be configured using a linear scale parallel to the X-axis direction or the Y-axis direction and a reading head. The X-axis direction position detection unit and the Y-axis direction position detection unit output the positions of the holding table 42 in the X-axis direction and the Y-axis direction to the control unit 100, respectively.

Note that the position of the holding table 42 in each axis direction detected by each position detection unit is determined with a predetermined reference position of the processing apparatus 30 as a reference. That is, the respective positions in the processing apparatus 30 according to the first embodiment are determined with the predetermined reference positions as the references.

The control unit 100 controls each of the above-described components of the processing apparatus 30 to cause the processing apparatus 30 to perform a processing operation on the wafer 1. Note that the control unit 100 is a computer that includes an arithmetic processing device including a microprocessor such as a central processing unit (CPU), a storage device including a memory such as a read only memory (ROM) or a random access memory (RAM), and an input/output interface device. In the arithmetic processing device of the control unit 100, the arithmetic processing device performs arithmetic processing according to a computer program stored in the storage device and outputs a control signal for controlling the processing apparatus 30 to the above-described components of the processing apparatus 30 via the input/output interface device.

In addition, the processing apparatus 30 is connected to a display unit (not illustrated), which is connected to the control unit 100 and configured using a liquid crystal display device or the like that displays a state of the processing operation, an image, and the like, and an input unit which is connected to the control unit 100 and used when an operator registers processing content information or the like. In the first embodiment, the input unit includes at least one of a touch panel provided on the display unit and an external input device such as a keyboard.

### Mark Formation Step

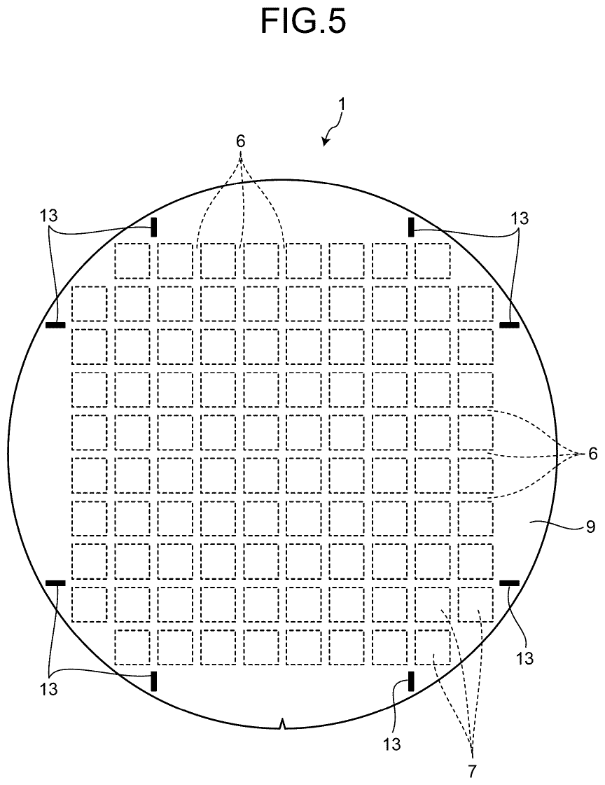

FIG. 5 is a plan view of the wafer after the mark formation step of the method of processing a wafer illustrated in FIG. 2 as viewed from the back surface side. FIG. 6 is a plan view of another example of the wafer illustrated in FIG. 5 as viewed from the back surface side. The mark formation step 1002 is a step of forming the marks 13 indicating the positions of the planned dividing lines 6 of the wafer 1 on the back surface 8.

In the first embodiment, in the mark formation step 1002, in the processing apparatus 30, a processing condition is registered in the control unit 100 by the operator, and the front surface 3 side of the wafer 1 before being subjected to cutting after the tape arrangement step 1001 is placed on the holding surface 441 of the holding table 42 positioned in the loading and unloading area with the tape 11 interposed therebetween. In the first embodiment, the processing apparatus 30 starts the processing operation, that is, the mark formation step 1002 when the control unit 100 receives an instruction to start the processing operation from the operator in the mark formation step 1002.

In the first embodiment, in the mark formation step 1002, when the processing apparatus 30 starts the processing operation, the control unit 100 causes the front surface 3 side of the wafer 1 to be sucked and held onto the holding surface 441 with the tape 11 interposed therebetween to expose the back surface 8 of the wafer 1 upward. In the first embodiment, in the mark formation step 1002, the control unit 100 of the processing apparatus 30 controls the X-axis moving unit 61 and the Y-axis moving unit 62 to position the lower imaging unit 80 below the wafer 1 held by the holding portion 44 of the holding table 42.

In the first embodiment, in the mark formation step 1002, the control unit 100 of the processing apparatus 30 causes the lower imaging unit 80 to capture an image of the wafer 1 from below through the holding portion 44 and the tape 11, acquires the image obtained by the capturing, and detects the planned dividing lines 6 from the acquired image. In the first embodiment, in the mark formation step 1002, the control unit 100 of the processing apparatus 30 controls the X-axis moving unit 61 and the Y-axis moving unit 62 such that the condenser lens of the laser beam irradiation unit 50 and a position at which the mark 13 determined in the processing condition is to be formed on the back surface 8 based on positions of the detected planned dividing lines 6 face each other in the Z-axis direction.

In the first embodiment, in the mark formation step 1002, the control unit 100 of the processing apparatus 30 controls the X-axis moving unit 61 to move the holding table 42 in the X-axis direction and causes the laser beam irradiation unit 50 to irradiate the position on the back surface 8 where the mark 13 determined in the processing condition is to be formed with a laser beam. Then, the metal layer 9 at the position irradiated with the laser beam on the back surface 8 of the wafer 1 is subjected to ablation to form the mark 13 as a groove. In this manner, in the mark formation step 1002 of the first embodiment, the processing apparatus 30 forms the marks 13 based on the planned dividing lines 6 detected by imaging of the lower imaging unit 80.

Note that, in the first embodiment, in the mark formation step 1002, as illustrated in FIG. 5, the processing apparatus 30 forms the mark 13 in the outer peripheral marginal area 5 of the back surface 8 of the wafer 1 and on an extension line of the center in the width direction of the planned dividing lines 6. In addition, in the first embodiment, in the mark formation step 1002, the processing apparatus 30 forms the marks 13 on the extension lines of centers in the width direction of the planned dividing lines 6 every predetermined number of the planned dividing lines 6. In addition, in the present disclosure, in the mark formation step 1002, the processing apparatus 30 may form the marks 13 on the extension lines of the centers in the width direction of all the planned dividing lines 6 in the outer peripheral marginal area 5 of the back surface 8 of the wafer 1.

In addition, in the present disclosure, in the mark formation step 1002, as illustrated in FIG. 6, the processing apparatus 30 may form cross-shaped marks 13 at intersections among the planned dividing lines 6 in the device area 4 on the back surface 8 of the wafer 1. In this manner, in the present disclosure, in the mark formation step 1002, the marks 13 may be formed in the cross shape and formed at positions corresponding to the intersections among the planned dividing lines 6.

In addition, in the present disclosure, the marks 13 are formed on the extension lines of the centers in the width direction of every predetermined number of the planned dividing lines 6 in the outer peripheral marginal area 5 on the back surface 8 of the wafer 1 or at the positions corresponding to the intersections among the planned dividing lines 6 in the mark formation step 1002, and thus, are formed in areas that correspond to the planned dividing lines 6 and are to be removed in the dicing step 1003.

### Dicing Step

FIG. 7 is a perspective view schematically illustrating the dicing step of the method of processing a wafer illustrated in FIG. 2. The dicing step 1003 is a step of dicing the wafer 1 from the back surface 8 side using the marks 13 formed in the mark formation step 1002 as references to divide the wafer 1 into the individual chips 10.

In the first embodiment, in the dicing step 1003, a cutting apparatus 90 illustrated in FIG. 7 sucks and holds the front surface 3 side of the wafer 1 on a holding surface of a holding table (not illustrated) with the tape 11 interposed therebetween, and clamps the frame 12 with a clamp unit (not illustrated) around the holding table. In the first embodiment, in the dicing step 1003, the cutting apparatus 90 captures an image of the back surface 8 side of the wafer 1 held on the holding surface of the holding table with an imaging unit (not illustrated), and detects the marks 13 from the image obtained by the capturing.

In the first embodiment, in the dicing step 1003, the cutting apparatus 90 performs alignment for aligning a cutting blade 92 of a cutting unit 91 and the planned dividing line 6 of the wafer 1 based on positions of the detected marks 13, an interval between the planned dividing lines 6, and the like. In the first embodiment, in the dicing step 1003, as illustrated in FIG. 7, the cutting apparatus 90 performs cutting on the wafer 1 along the planned dividing lines 6 to divide the wafer 1 into the individual chips 10 by causing the cutting blade 92 rotating about an axis to be cut into the planned dividing line 6 of the wafer 1 until reaching the tape 11 while relatively moving the cutting blade 92 of the cutting unit 91 and the wafer 1 along the planned dividing lines 6.

In the first embodiment, in the dicing step 1003, when the cutting is performed on all the planned dividing lines 6 of the wafer 1, the cutting apparatus 90 retracts the cutting unit 91 from the wafer 1 and moves the holding table to the loading and unloading area. In the first embodiment, in the dicing step 1003, the cutting apparatus 90 stops the suction and holding of the holding table positioned in the loading and unloading area, releases the clamping of the frame 12 by the clamp unit, and ends the processing operation, that is, the dicing step 1003.

In the method of processing a wafer according to the first embodiment described above, the marks 13 indicating the planned dividing lines 6 are formed on the metal layer 9 laminated on the back surface 8 of the wafer 1 before the dicing step 1003.

For this reason, in the method of processing a wafer according to the first embodiment, the positions of the planned dividing lines 6 can be identified even if the front surface 3 side of the wafer 1 is bonded to the tape 11 to prevent foreign matter from adhering to the devices 7, and the metal layer 9 is formed on the back surface 8 side of the wafer 1.

As a result, in the method of processing a wafer according to the first embodiment, the cutting can be easily performed on the planned dividing lines 6 even in the wafer 1 in which the front surface 3 side of the wafer 1 is bonded to the tape 11 in order to prevent foreign matter from adhering to the devices 7 and the metal layer is laminated on the back surface 8 side.

According to the present disclosure, it is possible to easily process a planned dividing line even in a wafer including a metal layer laminated on a back surface side.

Although the invention has been described with respect to specific embodiments for a complete and clear disclosure, the appended claims are not to be thus limited but are to be construed as embodying all modifications and alternative constructions that may occur to one skilled in the art that fairly fall within the basic teaching herein set forth.

What is claimed is:

1. A method of processing a wafer, the wafer including on a side of a front surface a plurality of intersecting planned dividing lines and a plurality of devices formed in respective areas defined by the planned dividing lines, and a metal layer laminated on a side of a back surface, the method comprising:
forming a mark indicating positions of the planned dividing lines of the wafer on the back surface; and
dicing the wafer from the side of the back surface using the formed mark as a reference to divide the wafer into individual chips.

2. The method of processing a wafer according to claim 1, wherein,
forming the mark includes
holding the side of the front surface of the wafer by a holding table including a holding surface at least a part of which is made of a transparent material, and
capturing an image of the side of the front surface of the wafer through the holding surface to detect the planned dividing lines, the mark being formed based on the detected planned dividing lines.

3. The method of processing a wafer according to claim 1, wherein the mark is formed in an area that corresponds to the planned dividing lines and is to be removed in dicing the wafer.

4. The method of processing a wafer according to claim 3, wherein the mark is formed in a cross shape and is formed in an area that corresponds to an intersection of the planned dividing lines and is to be removed in dicing the wafer.

5. The method of processing a wafer according to claim 1, wherein the wafer is made of SiC.
